(19) United States
(12) Patent Application Publication
(10) Pub. No.: US 2003/0098699 A1
(43) Pub. Date: May 29, 2003

(54) Sense interface system with velocity feed-through rejection

(76) Inventors: Mark A. Lemkin, El Cerrito, CA (US); Jason C. Jones, Berkeley, CA (US); Steven J. Sherman, Lexington, MA (US); Thor N. Juneau, Berkeley, CA (US); William A. Clark, Fremont, CA (US)

Correspondence Address: VIERRA MAGEN MARCUS HARMON & DENIRO LLP, 685 MARKET STREET, SUITE 540, SAN FRANCISCO, CA, 94105, US

(21) Appl. No.: 09/990,627

(22) Filed: Nov. 16, 2001

(51) Int. Cl. G01R 27/26

(52) U.S. Cl. 324/678

(57) ABSTRACT

A capacitive sensing circuit coupled to a variable capacitor. The circuit comprises a sense pulse generator providing a first polarity sense pulse and a second polarity sense pulse; a sense capacitor coupled to the sense pulse generator; a charge detector coupled to the sense capacitor; and a storage device coupled to the charge detector. The storage device may be a sample and hold circuit, a capacitor or a buffer. Multiple capacitors may be provided to enable a position detection scheme which is suitable for use in an optical mirror switching array. An analog to digital converter may be coupled to the storage device and a digital demodulator device coupled to the output of the analog to digital converter.

### BACKGROUND OF THE INVENTION

1. Field of the Invention

The invention is directed towards a device for position sensing based on sense-capacitor measurement, and in particular, to an apparatus for sensing the position of a mirror using capacitive sensing in an optical switching apparatus.

2. Description of the Related Art

Decreasing the size of micro-machined components while increasing their performance has required that the electronics used in such applications play an increasing role in the sensing systems used therein. Generally, in such systems, the electronics must amplify and condition extremely small outputs from the sensing elements.

Micro machined components find applications in, for example, accelerometers, gyroscopes, and optical mirror switch arrays. In some systems, small capacitances must be measured. Techniques for sensing small displacements include using capacitive transducers formed, in part, from the structures undergoing displacements. In these applications, sense electronics are often included to detect and amplify the minute capacitance changes resulting from small mechanical displacements.

Capacitive interfaces have several attractive features. One particular advantage is that they can be incorporated into many standard micro machining processes with minimal additional processing steps. Capacitive transduction mechanisms are also compatible with CMOS sense interfaces and circuit techniques; CMOS circuits are particularly able to take advantage of progress made in increases in integration density. Furthermore, capacitors can operate as both sensors and actuators, making them particularly suited for optical mirror switch arrays. Also, the devices manufactured using standard semiconductor processing techniques can be extremely sensitive.

The dual operation of capacitors as actuators and sensors presents special problems in interface design.

One problem is that long term stability of such devices is difficult to attain. Another problem arises when a stationary or quasi-stationary voltage potential is placed between the movable proof-mass and stationary electrodes. Often, position sensing is performed using time-multiplexing (or alternatively frequency-multiplexing) techniques in which capacitors act as both a force transducer and a position sense element. In such cases, a force pulse will be applied to a force transducer, followed by a sense pulse across a sense transducer. During sensing, a charge is produced in response to a voltage-pulse (or alternatively voltage produced in response to a charge-pulse) across the sense capacitor, the amount of charge reflecting the relative position of the elements of the structure making up the capacitor. In some applications, a single capacitor may be used for both force actuation and position detection, or a plurality of sensing and forcing capacitors may share a common electrical node. In this case, when a quasi-stationary voltage is applied, changes in displacement can cause a current to be generated due to the changing capacitance. If this current flows into a sense interface, such as a charge integrator or an input terminal of a voltage buffer, an error signal will result. For example, a quasi-stationary voltage may be applied between the proof-mass and a stationary electrode in a mirror that is part of a feedback system; the quasi-stationary voltage used for applying a force for steering the mirror to a desired orientation. In this case, a slowly-varying feedback voltage may be present across one set of actuation capacitors, while a second, high-frequency modulation voltage is applied to a set of sense capacitors and is used for detecting displacement via capacitance measurements.

When a capacitive position transducer is utilized for position detection, this displacement current can cause a velocity feed-through error. In this case, a voltage applied to a capacitive transducer (e.g. for applying a force to move a micro-mechanical structure) in conjunction with movement of the structure during the period of time that position-sensing occurs will provide an error in the measurement related to the velocity of the micro-mechanical structure. Known modulation methods, such as correlated double sampling (CDS) or continuous-time modulation may be used in an attempt to cancel this source of error, but these methods fail to cancel the feed-through error because of the change in displacement over the correlated double sampling period; thus this feed-through is still coupled to the sense-interface output. The magnitude of this error may be substantial in cases where sense and feedback means include air-gap capacitors (typical in mirror array sensing systems) and the feedback electrodes comprise a voltage substantially larger than the sense voltage. Correlated double sampling techniques are well known by those skilled in the art and may be known by other names such as output offset storage, input offset storage, and auto-zeroing (see e.g. Degrauwe, M, et al., “A micropower CMOS-instrumentation amplifier,” IEEE JSSC, pp. 805-7, June 1985.; Razavi, B., Data Conversion System Design, IEEE Press, Piscataway, N.J., 1995; Lee, W. “A 4-channel, 18b, sigma-delta modulator IC with chopped-offset stabilization,” ISSCC, pp. 238-9, 1996; Wongkomet, N, Boser, B. E., “Correlated double sampling in capacitive position sensing circuits for micromachined applications,” IEEE APCCAS, p. 723-6, 1998.)

For example, in the embodiment of a steerable mirror array, sense and feedback electrodes on each mirror have nominal values of approximately 10 fF and the feedback voltage may be as high as 230v. Velocity feedthrough is undesirable as it may provide the equivalent of negative (destabilizing) damping on the microstructure in a feedback circuit for certain transient motions.

In addition to velocity feed-through, electronic circuits when applied to sensing circuits have non-idealities such as temperature dependent offset and flicker noise. CDS or modulation helps attenuate this problem, but any signal processing which occurs after the demodulation will undergo signal corruption due to offset, drift, and flicker noise which is introduced in the downstream signal processing. Offset can be especially troublesome in single-ended signal paths in which the zero-output value may vary with respect to a reference value. The magnitude of the problem is compounded due to, for example: difficulty in providing good, chopped single ended amplifiers; ohmic drops on supply or bias busses which may vary over time or temperature; and variation of charge injection over supply, temperature or bias points in switched capacitor circuits.

The present invention addresses these issues.

### SUMMARY OF THE INVENTION

In one embodiment the invention comprises a capacitive sensing circuit coupled to a variable capacitor. The circuit comprises a sense pulse generator providing a first polarity sense pulse and a second polarity sense pulse; a charge detector coupled to the sense capacitor; and a storage device coupled to the charge detector.

In one embodiment the storage device is a sample and hold circuit, but it may also comprise a capacitor and a switch.

In additional embodiments, multiple capacitors are provided to enable a position detection scheme which is suitable for use in an optical mirror switching array. In one such embodiment, four capacitors may be used with a mirror to provide two degrees of freedom position detection.

Still further embodiments of the invention may include an analog to digital converter coupled to the storage device and a digital demodulator device coupled to the output of the analog to digital converter.

In a further embodiment, the invention comprises a sampled data system having two phases. The system includes a sense transducer and a sense pulse generator as well as detection circuitry. In the system, a first phase zeroes an output of the sense transducer and a second phase detects the measurement of the position of a body coupled to the sense transducer. The system may also include a sense pulse generator providing a sense pulse to the sense transducer, the generator providing a first polarity of said sense pulse to said sense transducer during a first incidence of said first phase and said second phase, and a second polarity of said sense pulse to said sense transducer during a second incidence of said first phase and said second phase.

In yet another embodiment, the invention is a method of operating a circuit. The method may comprise the steps of: providing one or more sense pulses having a first polarity to a transducer during a first phase to obtain a first output; providing one or more sense pulses having a second polarity to a transducer in the circuit during a second phase to obtain a second output.

These and other objects and advantages of the present invention will appear more clearly from the following description in which the preferred embodiment of the invention has been set forth in conjunction with the drawings.

### BRIEF DESCRIPTION OF THE DRAWINGS

The invention will be described with respect to the particular embodiments thereof. Other objects, features, and advantages of the invention will become apparent with reference to the specification and drawings in which:

FIG. 1 is a schematic diagram of a capacitive sense interface.

FIG. 1A is a timing diagram.

FIG. 1B is a diagram showing an output with position and velocity components.

FIG. 1C is a diagram showing the sum of position and velocity components.

FIG. 1D is a diagram showing the output of a storage device.

FIG. 2 is a schematic diagram of an embodiment of the present invention.

FIG. 2A is a timing diagram.

FIG. 2B is a diagram showing an output with position and velocity components.

FIG. 2C is a diagram showing the sum of position and velocity components.

FIG. 2D is a diagram showing the output of a storage device.

FIG. 2E is a schematic diagram of one embodiment of an analog demodulator.

FIG. 2F is a diagram showing a representation of a demodulator output.

FIG. 3 is a schematic diagram of an alternate embodiment of the present invention.

FIG. 4 is a schematic diagram of a mirror with sense and feedback capacitors.

FIG. 5 is a schematic diagram of another embodiment of the invention.

FIG. 6 is a schematic diagram of a sense-pulse generator.

FIG. 7 is a timing diagram.

FIG. 8 is a close-up of the timing diagram of FIG. 7.

Like reference numerals refer to corresponding parts throughout all the views of the drawings.

### WRITTEN DESCRIPTION

The invention comprises a system and apparatus for correction of position errors in a capacitive-sensing network. In one particular embodiment, the invention finds particular applicability in an optical switch array, but those of average skill in the art will find a multitude of examples where the principles of the invention are applicable, including other systems where capacitive transducers are used for applying a force to or measuring the position of micro-mechanical structures.

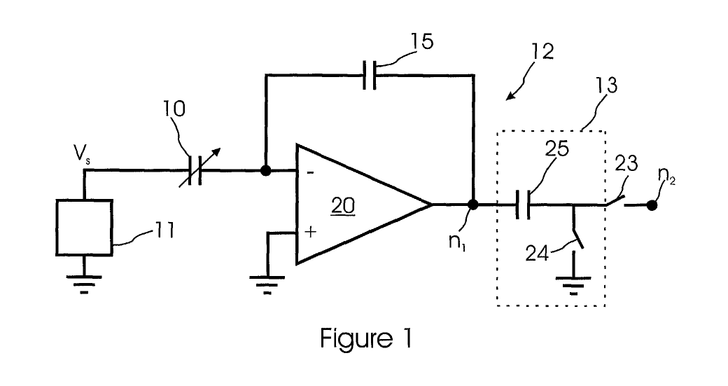

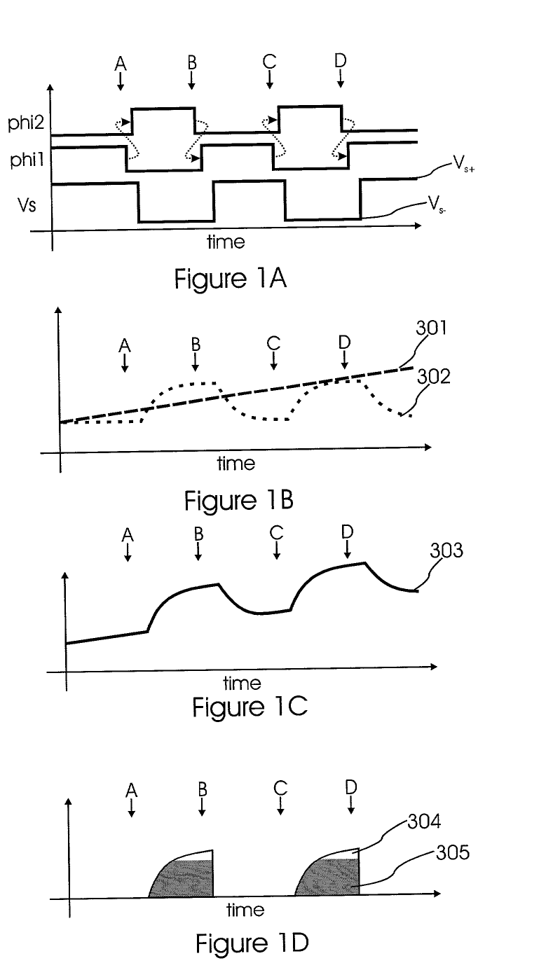

Referring to FIG. 1, a capacitance sensing circuit includes, in one embodiment, one or more sense capacitors 10; a front-end 12, comprising amplifier 20 in conjunction with feedback capacitor 15, coupled to the sense capacitors; sense-pulse generator 11 connected to the sense capacitors; and a storage device 13. Note that a resistor may be placed in parallel with feedback capacitor 15 to set the DC bias of output of amplifier 20. Alternatively, a switch may effect a resistor by periodically closing the switch for brief periods, or a switched-capacitor resistor may be used as a resistor. While in this embodiment storage device 13 comprises a sampling capacitor 25 in conjunction with switch 24, in an alternate embodiment, storage device 13 may be replaced with, for example, a sample-and-hold amplifier. Furthermore, additional elements may be introduced before or after storage device 13, including amplification or buffering stages. In this example, the variable capacitor may be a portion of a micromechanical mirror or inertial device whose position is to be sensed. The variable capacitor 10 may comprise, for example, interdigitated comb fingers (as described in U.S. Pat. No. in Tang et al., 5,025,346, issued Jun. 18, 1991, hereby incorporated by reference), or parallel-plate configurations (as described in U.S. Patents Diem et al., U.S. Pat. Nos. 5,495,761, issued Mar. 5, 1996; Aksyuk, et al., 6,265,239, issued Jun. 24, 2001; and Bhalla et al., 6,275,326, Aug. 14, 2001 all hereby incorporated by reference)

Operation of the circuit of FIG. 1 is now described with reference to FIGS. 1A through 1J. Note that phi1 and phi2 may be generated using a non-overlapping clock generator, such as a cross-coupled nand or nor pair with inverter delays at the nand or nor outputs. Switch 24 is closed when phi1 is high and open when phi1 is low. Switch 23 is closed when phi2 is high and open when phi2 is low. During the period up to time instant A, when phi1 is high and phi2 is low, sense pulse generator 11 applies a first voltage Vs+ to the independent terminal of the sense capacitor. The output of amplifier 20, node n1, settles to a value V_{oA} having undesired components due to offset and flicker noise, as well as desired components due to the sense capacitance. At time period ‘A’ phi1 drops, opening switch 24, thereby sampling n1 (having a voltage V_{oA}) across capacitor 25. Phi2 then rises, connecting node n2 to n1 through capacitor 25 and switch 23. As phi2 rises, and before Vs changes, n2 is equal to the ground potential since offset has been stored on capacitor 25. Thus, the storage device subtracts amplifier errors including offset and low-frequency flicker noise from the output n1. After phi2 has risen, sense pulse generator 11 applies a second voltage Vₛ₋to sense capacitor 10. Assuming that the capacitance of sense capacitor 10 is constant over the entire period between ‘A’ and ‘B’, at time ‘B’n2 is equal to:

$${V}_{n2} = ( {V}_{s +} - {V}_{s -} ) \frac{{C}_{10}}{{C}_{15}}$$

thereby effecting a CDS operation. In Equation 1 C₁₀ and C₁₅ are the values of capacitors 10 and 15, respectively.

FIGS. 1B through 1D illustrates how CDS fails to remove velocity feed-through from the output of the position sense interface. Suppose that capacitor 10 is changing due to motion between a stationary plate and a movable plate. Furthermore, suppose that the sense pulse generator maintains a quasi-stationary or slowly varying bias voltage Vₛ₀>>ΔVₛ to apply force feedback, e.g. so that Vₛ₊+Vₛ₀+ΔVₛ, Vₛ₋=Vₛ₀ (See U.S. Pat. No. 5,345,824, Sherman et al., Sep. 13, 1994 for an example of an application using a quasi-stationary bias combined with sense pulses to attain forcing and sensing from a capacitor). FIG. 1B shows separate voltage components from position, 302, and velocity feed-through, 301, at node n1 versus time. Velocity feed-through component 301 is caused by a current, hereby termed a ramping current, flowing from capacitor 10 induced by the varying capacitance subjected to a quasi-constant voltage. The result of the ramping current is a continuous ramping at node n1, shown in FIG. 1B, as this displacement current is integrated into a voltage by amplifier 20 in conjunction with capacitor 15. FIG. 1C shows the combined output 303 at node n1 including both velocity feed-through term 301 and the nominal position signal component 302.

Referring to FIG. 1, in conjunction with timing diagram FIG. 1A and combined output waveform 303, the output versus time at node n2, may be derived as shown in FIG. 1D. In FIG. 1D, the area 305 illustrates the post-CDS output at node n2 one would expect from the capacitance: a value directly related to the relative position of the terminals of capacitor 10. Note the presence of error region 304 at node n2 caused by velocity feedthrough: an error term that grows larger over time. Node n2 is sampled at time instants B (or equivalently, D) to give an output voltage (assuming amplifier 20 is fast) approximately equal to:

$${V}_{n2} \approx \underbrace{Δ {V}_{s} \frac{{C}_{10} {\vert}_{t = B}}{{C}_{15}}}_{Position Term} - \underbrace{{V}_{s0} \frac{\frac{ⅆ {C}_{10}}{ⅆ t} Δ t}{{C}_{15}}}_{Velocity Feed - Through}$$

assuming the rate of capacitance change over time, dC₁₀/dt, is constant, where Δt is the elapsed time between time instants A and B.

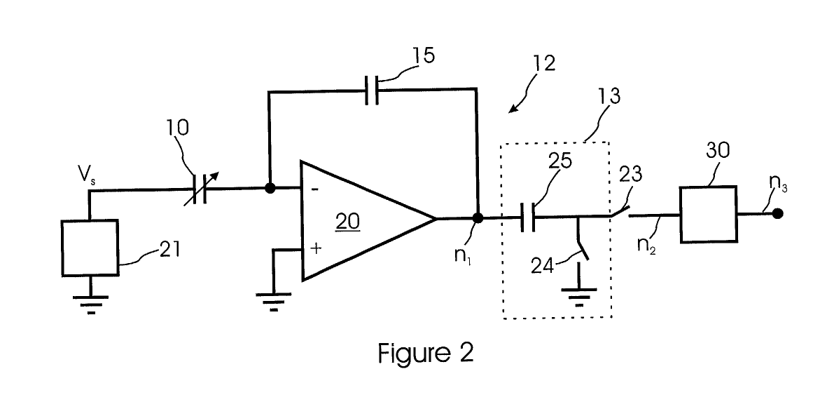

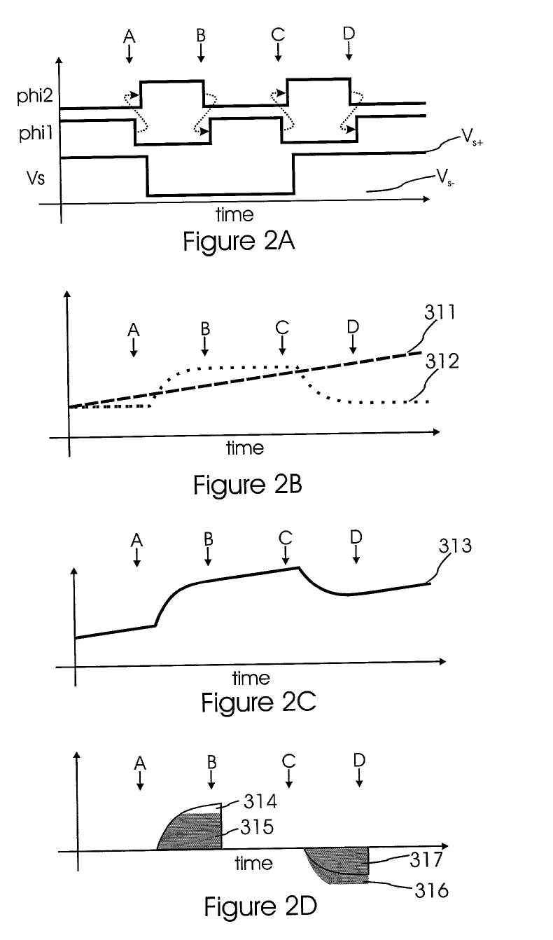

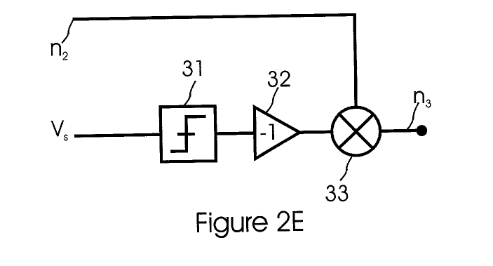

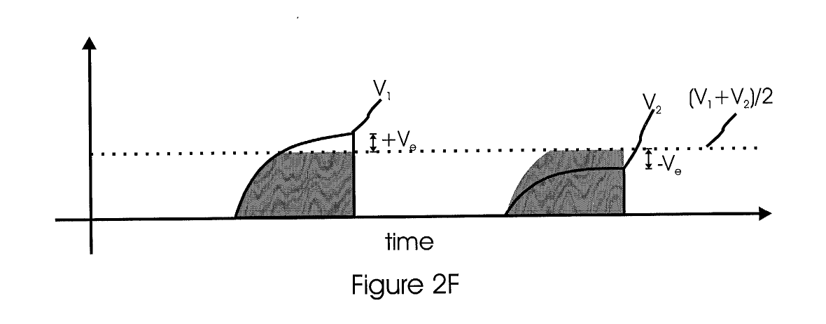

To eliminate velocity feed-through error, in accordance with the invention and referring to FIGS. 2 and 2A-E, a modulated sense-pulse separates the velocity and position components of the output of the sensing amplifier, after which a demodulation and filtering operation may be performed to attain velocity feed-through rejection. Sense-pulse modulation may be attained by applying a first sense pulse having a first polarity during a first sampling period and a second sense pulse having an opposite polarity during a second sampling period. Sense pulse polarity is defined as the edge direction (low to high or high to low) applied by the sense pulse generator to the sense capacitor after the storage device has sampled the first output of the front-end, between the two periods that CDS operates.

In FIG. 2, a capacitance sensing circuit with velocity feed-through cancellation includes, in one embodiment, one or more sense capacitors 10; a front-end 12, comprising amplifier 20 in conjunction with feedback capacitor 15, coupled to a sense capacitor; sense-pulse generator 21 connected to a sense capacitor; storage device 13; and a demodulator 30. Note that the DC bias of front-end 12 may be set as described above.

Operation of the circuit of FIG. 2 is now described with reference to FIGS. 2A-E. During the period up to time instant A, when phi1 is high and phi2 is low, sense pulse generator 21 applies a first voltage Vs+ to the independent terminal of the sense capacitor. The output of amplifier 20, node n1, settles to a value V_{oA} having undesired components due to offset and flicker noise, as well as desired components due to the sense capacitance. At time period ‘A’ phi1 drops, opening switch 24, thereby sampling n1 (having a voltage V_{oA}) across capacitor 25. Phi2 then rises, connecting node n2 to n1 through capacitor 25 and switch 23. As phi2 rises, and before Vs changes, n2 is equal to the ground potential since offset has been stored on capacitor 25. Thus, the storage device subtracts amplifier errors including offset and low-frequency flicker noise from the output n1. After phi2 has risen, sense pulse generator 21 applies a second voltage Vₛ₋ to sense capacitor 10. Consistent with the discussion about velocity feed-through above, at time ‘B’ the voltage at node n2 is equal to:

$${V}_{n2} {\vert}_{t = B} \approx \underbrace{Δ {V}_{s} {C}_{10} \frac{{\vert}_{t = B}}{{C}_{15}}}_{Position Term} - \underbrace{{V}_{s0} \frac{ⅆ {C}_{10}}{ⅆ t} Δ \frac{t}{{C}_{15}}}_{Velocity Feed - Through}$$

as schematically illustrated in FIG. 2D. This output, is provided to demodulator 30.

After this first output, phi1 goes high followed by phi2 going low. Note that sense pulse generator 21 maintains the Vₛ₋ to the independent terminal of the sense capacitor. Node n1, by time period C, again settles towards a ramping value, V_{oC} the ramping being caused by the velocity feed-through. At time period ‘C’ phi1 falls, opening switch 24, thereby sampling n1 (having a voltage V_{oC}) across capacitor 25. Phi2 then rises, connecting node n2 to n1 through capacitor 25 and switch 23. After phi2 has risen, sense pulse generator 21 applies a voltage Vₛ₊ to sense capacitor 10. After settling, at time ‘D’, the voltage at node n2 is sampled and equal to:

$${V}_{n2} {\vert}_{t = D} \approx - \underbrace{Δ {V}_{s} {C}_{10} \frac{{\vert}_{t = D}}{{C}_{15}}}_{Position Term} - \underbrace{( {V}_{s0} + Δ {V}_{s} ) \frac{ⅆ {C}_{10}}{ⅆ t} Δ \frac{t}{{C}_{15}}}_{Velocity Feed - Through}$$

This output is also provided to demodulator 30. Note that at both time instants B and D, the component of Vₙ₂ due to velocity feed-through current is the same sign for a given direction of motion—it is not a function of the sense pulse polarity. This is in contrast to the position component, the sign of which is dependent on the polarity of the sense pulse.

Demodulator 30 may demodulate in the analog or the digital domain. If Demodulator 30 operates in the analog domain, demodulator 30 typically will comprise a nonlinear element synchronous with the flipping of the sense-pulse such as a mixer, a four-quadrant multiplier, or a simple chopper comprising at least two switches. In this embodiment, demodulator 30 may further include a low-pass filter after the nonlinear element and/or a high-pass filter before the nonlinear element.

FIG. 2E is a schematic diagram of one embodiment of an analog demodulator comprising comparator 31 inverting amplifier 32 and four quadrant multiplier 33. FIG. 2F illustrates the output of the demodulator, n3. Voltage V₁, includes an error of +Vₑ due to velocity feed-through, while voltage V₂ includes an error −Vₑ due to velocity feed-through, the first voltage being positive and the second voltage being negative due to the demodulator. If the demodulator output is followed by a low-pass filter, an output voltage equal to the average of these two values is constructed: a value including only the component due to position of the capacitors, thereby attenuating the effect of velocity feed-through. A filtered representation of the voltage at n3 is illustrated by the dotted line labeled (V₁+V₂)/2.

Many systems that use capacitive sensing include digital signal processing of the output of the sense channel. In this case, it is advantageous to incorporate demodulator 30 in digital software or hardware, after analog-to-digital (A/D) conversion of the output of the storage element. In this case, the demodulator will still typically include a nonlinear element such as a multiplier or a mixer. Digital demodulation following post-A/D conversion has little computational overhead; thus, digital demodulation can easily be designed into the digital components of the system. Moreover, other error sources including flicker noise, offset, offset shifts due to thermal drift in the output circuitry and A/D converter, pedestal error due to charge injection and variation in charge injection due to thermal or supply changes are modulated up to the sense-pulse modulation frequency where, with the velocity feed-through error, they may either be filtered out or ignored if beyond the bandwidth of interest.

Demodulation in the digital domain may be performed many different ways. For example, one may effect a simple synchronous demodulator by digital multiplication of the converted output with a square wave. For example, the digitized position-sense output is multiplied by −1 during the negative-edged output values and +1 during the positive-edged sense values.

In another alternative, demodulation may be performed by discrete-time differencing. The two output values are sampled and subtracted by a differencer. The output of the differencer is demodulated by multiplying with a synchronous square wave to give the correct sign. In yet another embodiment, a high-pass, or band-pass, filter may be coupled with synchronous demodulation. By including a high-pass filter before demodulation, the amount of low-frequency energy modulated up to the flip frequency is minimized. A high-pass filter may be realized by a low-pass filter in negative feedback. In yet another embodiment, a low-pass filter may be coupled with synchronous demodulation. By including a low-pass filter after demodulation, the high-frequency energy modulated up to the flip frequency is minimized. Design of high-, low- and band-pass digital filters is well known by those skilled in the art.

Sense pulse generator 21 may be implemented in any of a number of implementations. Sense-pulse generator 21 may comprise a T flip flop with an input coupled to phi2. In another embodiment, sense pulse generator 21 may comprise a half-rate clock signal generated by a clock divider operating on either phi1 or phi2, or a signal used in the generation of phi1 and phi2. The output of digital logic may directly be taken as the sense voltage Vs, or coupled to a circuit that uses the digital value to switch Vs between two or more values.

In the description of the present embodiment, modulation of the position and velocity to different frequencies has been attained by changing, or flipping, the polarity of the sense pulse, which has the effect of modulating the position component of the front-end output to the flip frequency while not affecting the velocity component of the front-end output. The component of the output due to velocity feed-through, or displacement current, is almost identical over both periods, changing only due to non-idealities in the sense capacitors and changes in the velocity (i.e. acceleration) of the plates comprising sense capacitor 10. Since the velocity component does not change much from sample to sample, it will have negligible energy at the flip frequency, and demodulator 30 may remove the velocity feed-through component of front-end output n1 quite effectively.

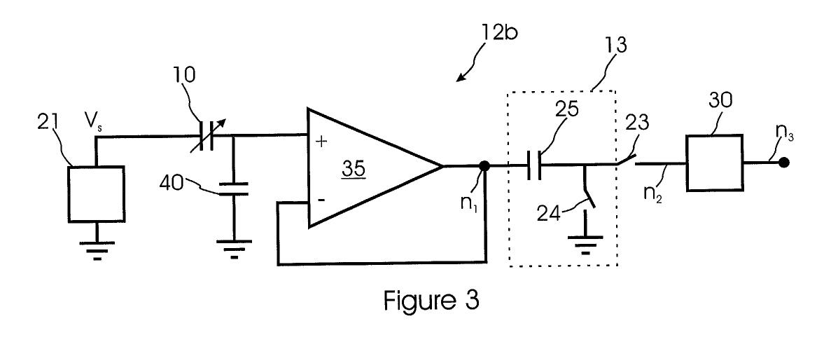

FIG. 3 is another embodiment of the invention. This embodiment operates in a manner similar to that shown in FIG. 2 except that a charge integrator is not used. Rather, in FIG. 3, the amplifier is configured as a non-inverting stage, such that the output follows the input signal, thereby effecting a charge detector; the charge generated in response to the sense pulse causes a voltage to be created on the input node. FIG. 3 shows amplifier 35 configured in unity-gain feedback, however, amplifier 35 may also be configured as a non-inverting gain stage by placing a first resistive or capacitive feedback element between n1 and the negative input terminal of amplifier 35, and a second resistive or capacitive feedback element between the negative input terminal of amplifier 35 and ground, the gain being set by the ratio of the resistive or capacitive elements. A portion or all of the parasitic capacitance represented by capacitor 40 may be bootstrapped, connecting the ground terminal to node n1, to provide increased front-end voltage gain. CDS techniques are still applied, as is sense-pulse modulation.

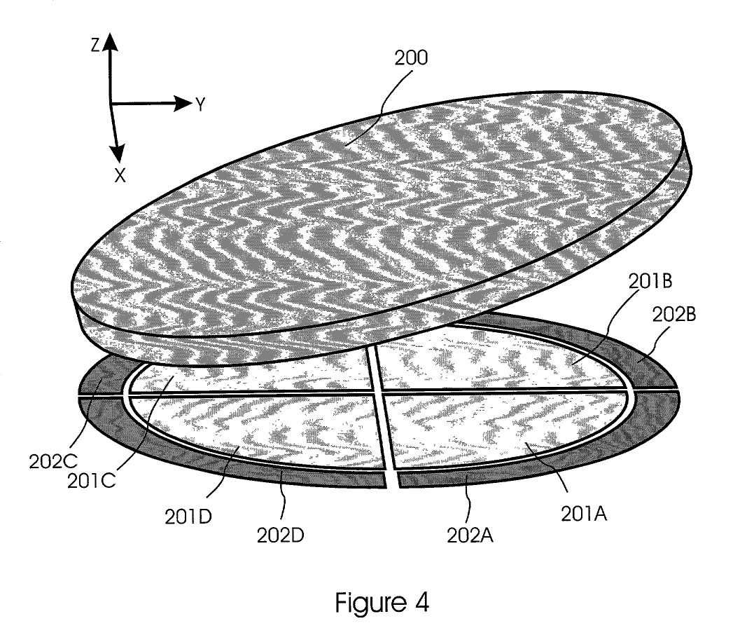

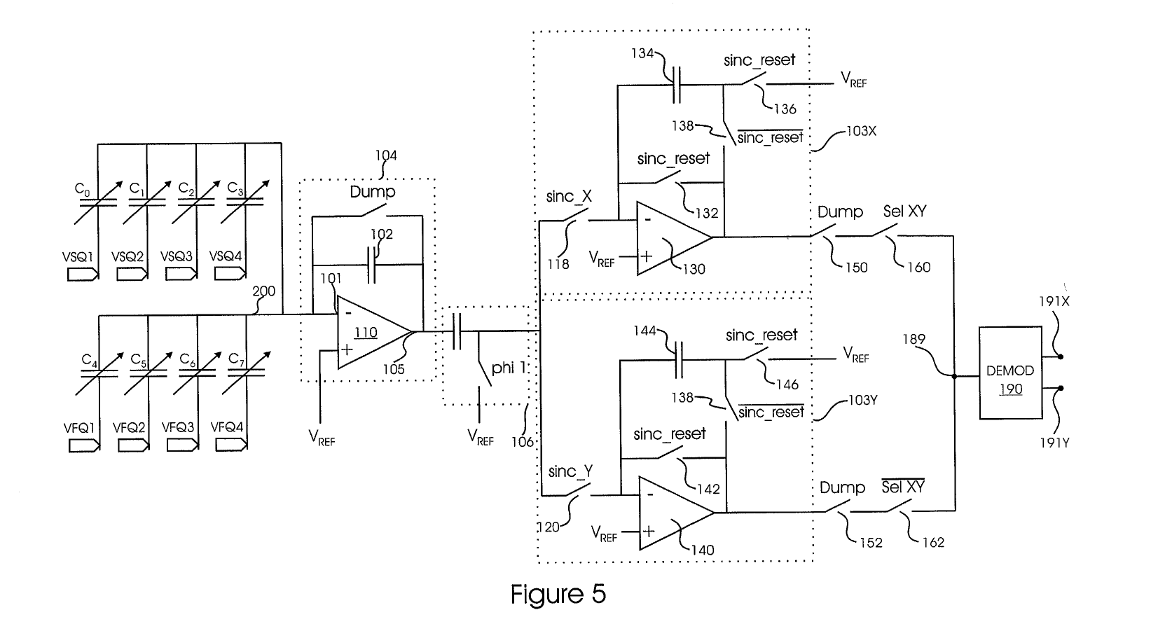

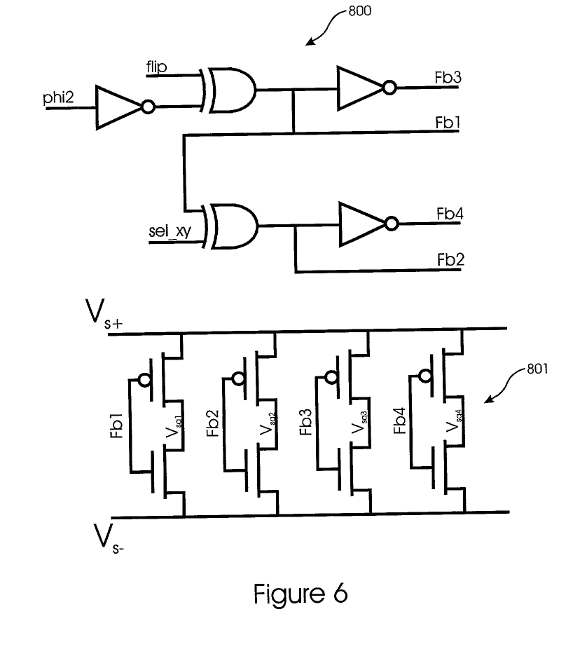

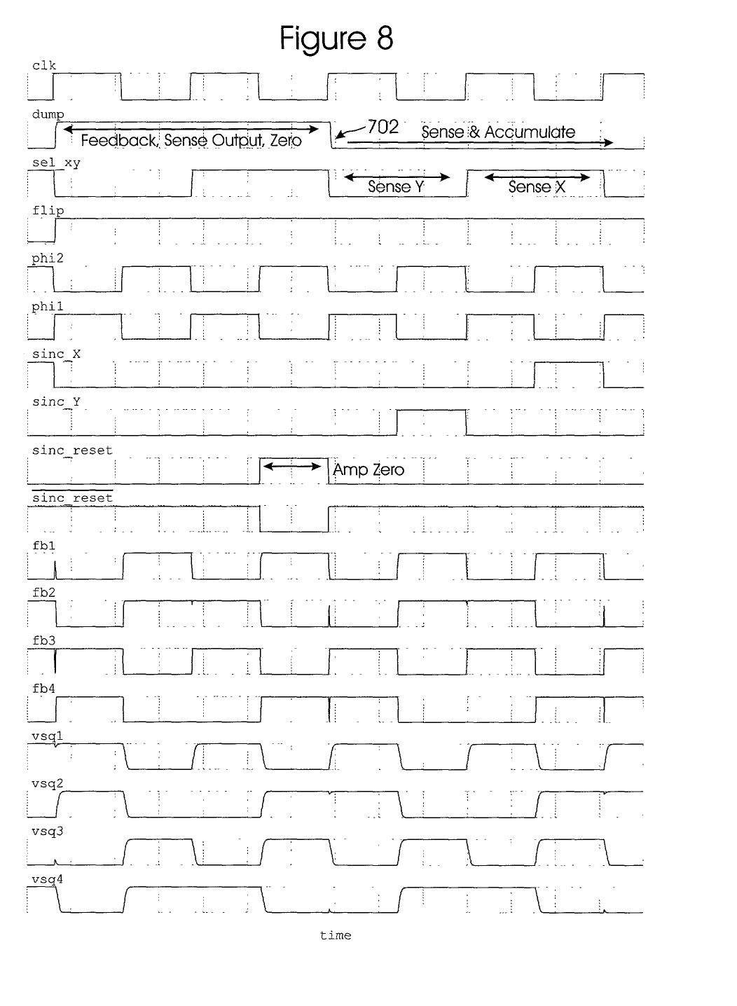

FIGS. 4-8 show another embodiment of the present invention. In this embodiment, two-channel position sensing is used to detect the orientation of a two-degree of freedom mirror for use in an optical switching array. The mirror coupled with the systems shown in FIGS. 5 and 6 may be provided in an optical switch array comprising a plurality of mirrors and circuits. An exemplary mirror is shown in FIG. 4 and has four quadrants, each quadrant having a force capacitor and a sense capacitor for the two degrees of freedom motion and detection. All capacitors share a common terminal with the mirror node 200, which is connected to the inverting input 101 of the front-end opamp 110. In this embodiment, electrostatic feedback is applied using four capacitors distinct from the sense capacitors, however alternate embodiments of the invention may include capacitors which provide both sensing and forcing functions. Four sense capacitors are formed with mirror 200 being a common electrical node with the other node of each sense capacitor given by: 201D (C₀), 201A (C₁), 201B (C₃), 201C (C₄). Four feedback capacitors are formed with mirror 200 being a common electrical node with the other node of each feedback capacitor given by: 202D (C₄), 202A (C₅), 202B (C₆), 202C (C₇). Mirror node 200 is electrically connected to the sense interface circuits by a conductive suspension (not shown).

Sense pulses are applied to individual sense capacitors in combination based on the rotational position (relative to FIG. 4) of the mirror which one seeks to measure. For example, to measure rotation about the x-axis, a differential sense-pulse is applied to sense pads 201D,C and 201A,B; that is, a sense-pulse of +ΔVₛ is applied to both 201D and 201C, and a sense pulse −ΔVₛ is applied to both 210A and 201B (ΔVₛ can be either positive or negative). To measure rotation about the y-axis, a differential sense-pulse is applied to sense pads 210A,D and 201B,C. Note that for this sensing configuration there will be a certain amount of cross-axis coupling under a displacement having a rotation about both axes (e.g. an Euler X,Y rotation); however, given both orientation-dependent differential capacitances detected by pulsing the quadrants as described above, the orientation may be backed out through proper reverse transformation.

Under an applied feedback or actuation voltage, applied to capacitors C4-C7, mirror motion causes an undesired ramping current coupled to the inverting input of the amplifier. The magnitude of the displacement current depends on both the applied voltage and the velocity of the mirror. The polarity of the current depends on the direction of motion as well as the polarity of the applied bias. This ramping current is integrated by charge integrator and captured, corrupting the output of the front-end 104 in a manner similar to that shown in FIGS. 1A-D.

Operation of the sense interface is now described with reference to FIG. 5 and FIGS. 7 and 8 starting at the time period that sinc_reset (ref 668) goes high. During this time the dump clock (ref 654) places front-end circuitry 104 in unity-gain feedback, thereby clearing any charge on capacitor 102 and driving both input 101 and output 105 towards reference voltage V_{ref}. Clock sinc_reset in conjunction with its complement sinc_reset bar (ref 670) clear sinc filters 103X and 103Y, storing amplifier (130 and 140) offset and flicker noise on capacitor 134 and 144. After sinc_reset and dump fall, the front-end amplifier is in charge-integration mode. Sensing begins by measuring y-axis differential capacitance: (C₀+C₁) - (C₂+C₃). During this first period of measurement flip is high (refs. 658, 602). To effect y-axis sense measurement, after phi1 (ref 662) rises, vsq1 is brought high, and vsq3 is brought low. After the front-end settles phi1 is brought low, causing storage device 106 to sample opamp offset and flicker noise. Switch 120, controlled by clock sinc_Y (ref. 665 ) is now closed, connecting sinc filter 103Y to the storage device, and a sense pulse is applied: vsq1 and vsq2 are brought low, and vsq3 and vsq4 are brought high. Front-end 104 integrates the charge from mirror node 200 resulting from this y-axis sense pulse, which is accumulated by sinc filter 103Y. The value accumulated on the sinc filter is sampled when sinc_Y falls, opening switch 120.

Next, x-axis differential capacitance: (C₀+C₃) - (C₁+C₂) is detected. To measure x-axis sense measurement, after sinc_Y falls phi1 rises, vsq1 is brought high, and vsq3 is brought low. After the front-end settles phi1 is brought low, causing storage device 106 to sample opamp offset and flicker noise. Switch 118, controlled by clock sinc_X (ref. 664) is now closed, connecting sinc filter 103X to the storage device, and a sense pulse is applied: vsq1 and vsq4 are brought low, and vsq2 and vsq3 are brought high. Front-end 104 integrates the charge from mirror node 200 resulting from this x-axis sense pulse, which is accumulated on sinc filter 103X. The value accumulated on the sinc filter is sampled when sinc_X falls, opening switch 118.

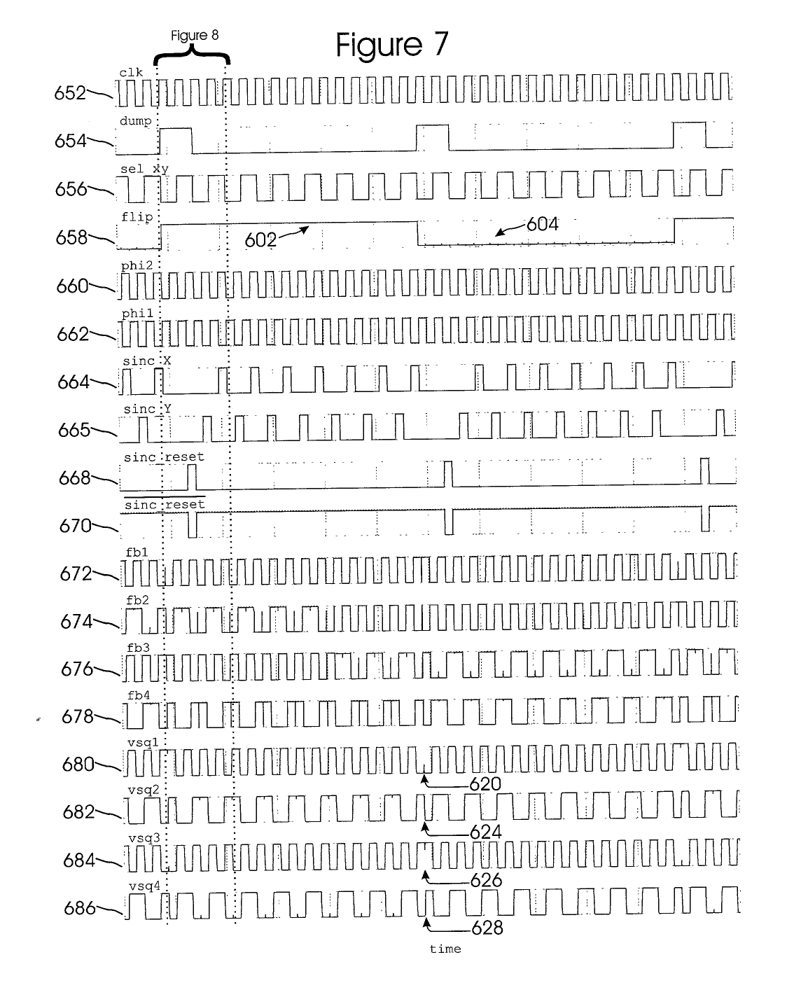

In this embodiment, the sinc filters 103X and 103Y accumulate seven samples (as shown in FIG. 7, reference nos. 602, 664 and 665) from charge integrator 104 in response to sense pulses having a first polarity as described above. After the seventh accumulation, during the period that dump is high, the sinc filters are connected, in succession, to multiplexed line 189 by switches 152 and 162 (Y-axis) and 150 and 160 (X-Axis). Demodulator 190, samples the sinc filter outputs as they are presented on the shared multiplexed line.

Feedback forces may be changed during the period that dump is high by changing the voltages applied to feedback pads 202A-D.

During the dump period, flip (ref. 658) changes polarity, going low. This has the effect of changing the polarity of the subsequent sense pulses, illustrated at 620, 624, 626 and 628 in FIG. 7. As the sense-pulse accumulation phase of the cycle starts again, after the sinc filters and front-end have been reset, sense pulses having an opposite polarity are now applied for the next seven pulse accumulations since flip is low (604). For example, for y-axis sensing, vsq1 and vsq2 are brought high, and vsq3 and vsq4 are brought low when sinc_Y is high and sampling the response of the charge integrator to the sense pulse. Similarly, for x-axis sensing, vsq1 and vsq4 are brought high, and vsq2 and vsq3 are brought low when sinc_X is high and sampling the response of the charge integrator to the sense pulse.

After the seventh accumulation with flip low, during the period that dump is high, the sinc filters are connected, in succession, to multiplexed line 189 by switches 152 and 162 (Y-axis) and 150 and 160 (X-Axis). Demodulator 190, again samples the sinc filter outputs as they are presented on the shared multiplexed line.

Note that the component of the output of the sinc filters due to the position from the first sample is the opposite sign of the output due to position during the second as a result of the switched polarity of the sense pulse. For the reasons described above, mirror motion between the time that phi1 falls and sinc_Y or sinc_X falls causes an undesired displacement current to flow into inverting input 101. The magnitude of the displacement current depends on both the voltages applied to the force electrodes, the sample interval between the falling edges of phi1 and sinc_X,Y, and the velocity of the mirror. The displacement current is integrated by the charge integrator 104, and filtered and amplified by sinc filters 103X,Y in a fashion identical to an output signal due to position. Since the component of sinc filter outputs due to the displacement current is identical over both flip periods, while the position is of opposite sign, the desired signal due to position may be extracted by the demodulator as described above. Note that in this embodiment, separate sensing and forcing capacitors are used; thus, the velocity feed-through component of the output is completely independent of the sense pulse voltage, and exact cancellation of the velocity feed-through term may be obtained when the mirror is moving with a constant velocity.

A further advantage of the invention is noted by recognizing that if feedback voltages are changed slowly (as compared to the flip frequency) during the time that the front-end is sampling the sense capacitances, the resulting feedback voltage feedthrough may be largely attenuated. Slow changes in the feedback voltage may be the result of unintentional droop of the feedback electrode voltage, or intentional changes of the feedback voltage during the sensing period.

Demodulator 190 may be of any of the forms previously described, and is easily implemented using a digital-signal processor following an ADC. To relax restrictions demodulator 190, demodulator 190 may in one embodiment, further comprise at least one sample-and-hold amplifier connected to line 189 that synchronously samples the output of the sinc filters as they are presented to line 190 during the period when dump is high. A sample-and-hold amplifier allows an analog-to-digital converter more time to acquire the output of the sinc filters. Once the signal is captured in the digital domain by the ADC, the digital representation of line 189 is de-multiplexed into two separate streams of sequential data, one per axis. These data streams are demodulated using a nonlinear element as described above, and presented at the output of the demodulator as digital representations of the position: 191X and 191Y. Since in this embodiment of a demodulator the SHA precedes the nonlinear element, offset and flicker noise in the SHA is removed from the desired position signal along with the velocity feed-through error.

FIG. 6 shows sense-pulse circuitry which generates sensing pulses on the sensing-pads 210A-D that form the independent terminals of the sense capacitors. The sense pulse generator includes combinatorial logic 800 having inputs phi2, flip, and sel_xy and logic outputs, Fb1Fb2, Fb3, and Fb4 wherein the outputs are dependent on the inputs according to the following truth table:

| flip | sel_xy | phi2 | Fb1 | Fb2 | Fb3 | Fb4 |
|---|---|---|---|---|---|---|
| 0 | 0 | 0 | 1 | 1 | 0 | 0 |
| 0 | 0 | 1 | 0 | 0 | 1 | 1 |
| 0 | 1 | 0 | 1 | 0 | 0 | 1 |
| 0 | 1 | 1 | 0 | 1 | 1 | 0 |
| 1 | 0 | 0 | 0 | 0 | 1 | 1 |
| 1 | 0 | 1 | 1 | 1 | 0 | 0 |
| 1 | 1 | 0 | 0 | 1 | 1 | 0 |
| 1 | 1 | 1 | 1 | 0 | 0 | 1 |

The logic output signals are connected to level converter 801 that produces analog sense pulses V_{sq1}, V_{sq2}, V_{sq3}, and V_{sq4} from two reference levels Vₛ₊ and Vₛ₋.

While sense pulse generator 800 and level converter 801 are compact and able to generate the necessary sense pulse levels and polarities from a small number of inputs for two axis sensing, it is understood that the invention includes other embodiments of sense-pulse generators or sense electrode configurations.

The foregoing description, for the purposes of explanation, used specific nomenclature to provide a thorough understanding of the invention. It is not intended to be exhaustive or to limit the invention to the precise form disclosed, obviously many modifications and variations are possible in view of the above teachings. Furthermore, it will be apparent to one skilled in the art that specific details are not required in order to practice the invention. For instance, while the invention has been described as being directed towards capacitive-position sensing interfaces, the invention comprises other embodiments including, but not limited to: piezoresistive- or piezoelectric-based sensing; a sense capacitor having only one independent node, as opposed to a capacitive bridge; continuous time modulation. Furthermore, it should be clear that implementation of the invention does not require a sinc filter, and if a sinc filter is included modulation of the sense pulse polarity more often than every time the sinc filter is cleared may be desirable. However, if a sinc filter is included and modulation is not synchronous with the dumping of the sinc filter, a demodulator is preferably included before the sinc filter to prevent the desired signal from being canceled. In yet other embodiments of the invention, two sense-pulses are provided with equal polarity but of differing magnitudes; sense pulses comprising a fixed charge are provided and a detector is included that is responsive to the charge-pulses (see, for example, Lemkin, et. al, U.S. patent application Ser. No. 09/765,521 filed Jan. 18, 2001, hereby incorporated by reference); and the storage device may comprise an analog-to-digital converter and a digital storage device, such as a memory, or a register.

The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

We claim:

1. An improved capacitive sensing circuit comprising:
a sense pulse generator providing a first polarity sense pulse and a second polarity sense pulse;
a sense capacitor coupled to the sense pulse generator;
a detector coupled to the sense capacitor; and
a storage device coupled to the detector.

2. The circuit of claim 1 wherein the storage device is a sample and hold circuit.

3. The circuit of claim 2 wherein the sample and hold circuit further comprises an amplifier and a capacitor.

4. The circuit of claim 1 wherein the storage device comprises a capacitor.

5. The circuit of claim 1 further including a filter coupled to the storage device.

6. The circuit of claim 1 wherein the sense pulse generator provides said first polarity sense pulse over a first phase and said second polarity sense pulse over a second phase.

7. The circuit of claim 6 further including a demodulation circuit coupled to the storage device.

8. The circuit of claim 7 wherein said demodulation circuit comprises a filter having an input and an output, and a nonlinear element having a first input, wherein said nonlinear element is selected from one of the following: a switch, a multiplier, a mixer.

9. The circuit of claim 8 wherein said filter includes a high-pass characteristic and said filter output is coupled to said first input of the nonlinear element.

10. The circuit of claim 8 wherein said filter includes a low-pass characteristic, said nonlinear element includes an output, and said filter input is coupled to said output of the nonlinear element.

11. The circuit of claim 8 wherein said nonlinear element further includes a second input coupled to a signal synchronous with sense pulse polarity.

12. The circuit of claim 8 wherein said demodulation circuit further comprises an input and an output, and an analog signal is provided to said demodulation circuit input.

13. The circuit of claim 8 wherein said demodulation circuit further comprises an input and an output, and a digital signal is provided to said demodulation circuit input.

14. The circuit of claim 1 further including a second sense capacitor coupled to the detector and the sense pulse generator.

15. The circuit of claim 14 further including a third and a fourth capacitor coupled to the detector and the sense pulse generator, wherein said sense pulse generator generates a first set of sense pulses on the first through fourth sense capacitors and a second set of sense pulses on the first through fourth sense capacitors.

16. The circuit of claim 15 wherein the first, second, third and fourth capacitors form a portion of a microstructure, and said detector comprises an output, said output being responsive to the orientation of said microstucture.

17. The circuit of claim 1 further including an analog to digital converter coupled to the storage device.

18. The circuit of claim 17 further including a demodulator coupled to the output of the analog to digital converter.

19. The circuit of claim 1 wherein said first sense pulse comprises a voltage pulse, and said second sense pulse comprises a voltage pulse.

20. The circuit of claim 1 wherein said first sense pulse comprises a charge pulse, and said second sense pulse comprises a charge pulse.

21. The circuit of claim 1 wherein said detector comprises a charge detector.

22. The circuit of claim 1 wherein said detector comprises a voltage detector.

23. A sampled data system having two phases, comprising:
at least a first sense transducer, said sense transducer comprising an output;
a first phase sampling said output of the sense transducer;
a second phase sampling said output of sense transducer, the difference between first and second samples providing a measurement of the position of a body coupled to the sense transducer; and
a sense pulse generator providing a sense pulse to the sense transducer, the generator providing a first polarity of said sense pulse to said sense transducer during a first incidence of said first phase and said second phase, and a second polarity of said sense pulse to said sense transducer during a second incidence of said first phase and said second phase.

24. The system of claim 23 further including a second sense transducer coupled to the sense pulse generator and receiving a sense pulse having the first polarity during a third incidence of said first and said second phase, and a sense pulse having the second polarity during a fourth incidence of said first and said second phase.

25. The system of claim 24 wherein the first sense transducer and the second sense transducer are coupled to a body having at least a first and a second degree of movement, the first sense transducer coupled to detect a change in said first degree of movement and the second sense transducer coupled to detect a change in said second degree of movement.

26. The system of claim 24 wherein the polarity of said sense pulse is controlled by a digital modulation signal.

27. The system of claim 23 further including a charge integrator coupled to the output of the sense transducer.

28. The system of claim 27 further including a storage device coupled to the output of the charge integrator.

29. The system of claim 28 further including a demodulator coupled to the output of the storage device

30. The system of claim 23 further including a buffer coupled to the output of the sense transducer.

31. The system of claim 30 further including a storage device coupled to the output of the buffer.

32. The system of claim 31 further including a demodulator coupled to the output of the storage device.

33. The system of claim 23 further including a charge detector coupled to the output of the sense transducer.

34. The system of claim 33 further including a storage device coupled to the output of the charge detector.

35. The system of claim 34 further including a demodulator coupled to the output of the storage device.

36. A circuit, comprising:
a sense capacitor coupled to a microstructure;
a charge detector coupled to the sense capacitor;
a sense pulse generator coupled to said sense capacitor, said sense pulse generator comprising control circuitry, said control circuitry causing the sense pulse polarity to invert over two phases; and
sense circuitry coupled to the charge detector detecting the difference between the phases.

37. The circuit of claim 36 wherein the charge detector comprises a buffer amplifier.

38. The circuit of claim 36 wherein the charge detector comprises a charge integrator.

39. The circuit of claim 36 wherein the sense circuitry comprises:
a storage device coupled to the charge detector;
a demodulator coupled to the storage device.

40. The circuit of claim 36 further including:
a storage device coupled to the charge detector;
an analog-to-digital converter coupled to the output of the storage device; and
a digital demodulator coupled to the analog-to-digital converter.

41. An optical mirror switch, comprising:
an optical mirror assembly;
at least one sense capacitor coupled to the optical mirror assembly;
sense circuitry coupled to the sense capacitor, including a sense pulse generator providing a first polarity sense pulse and a second polarity sense pulse, said sense pulse generator coupled to said sense capacitor;
a storage device coupled to the sense circuitry; and
a demodulator coupled to said storage device.

42. The optical mirror switch of claim 41 further including a plurality of sense capacitors coupled to the optical mirror, at least a first set of said plurality coupled to detect a position change in said mirror in a first direction and a second set of said plurality coupled to detect a position change in a second direction.

43. The optical mirror switch of claim 41 wherein said sense circuitry includes a charge detector.

44. The optical mirror switch of claim 41 wherein said sense circuitry includes a charge integrator.

45. A method of operating a switched-capacitor circuit, comprising:
providing a plurality of sense pulses having a first polarity to a sense capacitor during a first phase to obtain a first output of the sense transducer; and
providing a plurality of sense pulses having a second polarity to a sense capacitor during a second phase to obtain a second output of the sense transducer.

46. The method of claim 45 further including the step of storing the output of the sense capacitor.

47. The method of claim 45 further including the step of sampling an output of the sense capacitor

48. The method of claim 47 further including demodulating the output of the first and the second phases.

49. An improved capacitive sensing circuit comprising:
a sense pulse generator providing a first magnitude sense pulse and a second magnitude sense pulse;
a sense capacitor coupled to the sense pulse generator;
a charge detector coupled to the sense capacitor;
a storage device coupled to the charge detector; and
a demodulator coupled to the storage device.
